(19) United States
(12) Patent Application Publication
(10) Pub. No.: US 2014/0013044 A1
(43) Pub. Date: Jan. 9, 2014

(54) COMPUTER SYSTEM HAVING FUNCTION OF DETECTING WORKING STATE OF MEMORY BANK

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: BO TIAN, Shenzhen (CN); KANG WU, Shenzhen (CN)

(73) Assignee: HON HAI PRECISION INDUSTRY CO., LTD., New Taipei (TW)

(21) Appl. No.: 13/924,646

(22) Filed: Jun. 24, 2013

(30) Foreign Application Priority Data
Jul. 4, 2012 (CN) 201210229561X

(51) Int. Cl. G11C 29/12; G11C 7/10

(52) U.S. Cl. CPC G11C 29/12005; G11C 7/1072
USPC 711/105; 714/721

(57) ABSTRACT

A memory bank of a computer system includes a detection unit for detecting working state of a storage chip and a register chip of the memory bank. The detection unit detects whether the storage chip and the register chip work normally and outputs detection signals to a motherboard of the computer system according to the detection of the storage chip and the register chip. The motherboard performs predetermined operations according to the detection signals, thus indicating the working state of the storage chip and the register chip.

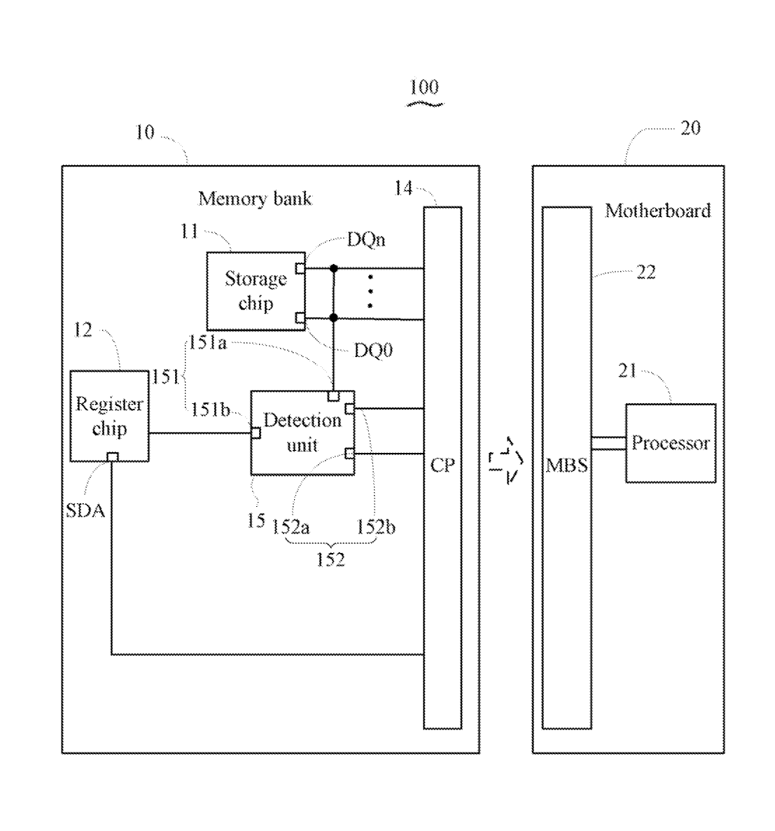

### CROSS-REFERENCE TO RELATED APPLICATIONS

This application is related to U.S. application Ser. No. 13/922,286, filed on Jun. 20, 2013, and titled “MEMORY BANK HAVING WORKING STATE INDICATION FUNCTION”.

### BACKGROUND

1. Technical Field

Embodiments of the present disclosure relate to computer systems, and particularly to, a computer system having a function of detecting a working state of a memory bank.

2. Description of Related Art

Many computer systems use a plurality of memory banks to improve performance of the computer systems. It is very important for a computer system to monitor the working states the memory banks. In some particular solutions, a detection circuit for detecting the working state of a memory banks is provided on a motherboard of the computer system, and a plurality of data lines are electronically connected between the detection circuit and data input/output (I/O) ports of the memory bank to detect whether the memory bank works normally. However, the detection of the data I/O ports can only indicate a working state of a storage chip (e.g., SRAM chip or DRAM chip) of the memory bank, and thus other components (e.g., register chip) of the memory bank cannot be detected by the detection circuit. Therefore, there is room for improvement in the art.

### BRIEF DESCRIPTION OF THE DRAWINGS

The figure illustrates a schematic block diagram of one embodiment of a computer system including a memory bank and a motherboard.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

Referring to the figure, a computer system 100 including a memory bank 10 and a motherboard 20 is shown. The memory bank 10 includes a storage chip 11, a register chip 12, a connection port (CP) 14, and a detection unit 15. The motherboard 20 includes a processor 21 and a memory bank socket (MBS) 22. The memory bank socket 22 may be, for example, a dual in-line memory module (DIMM). The connection port 14 may be, for example, an edge connector of the memory bank 11, which is inserted into the memory bank socket 22, to establish data communication between the memory bank 10 and the motherboard 20. The connection port 14 includes a plurality of data transmission pins configured to transmit data between the storage chip 11 and the motherboard 20.

The storage chip 11 may be, for example, a static random access memory (SRAM) chip, a dynamic random access memory (DRAM) chip, a synchronous dynamic random access memory (SDRAM) chip, or a double data rate SDRAM (DDR SDRAM) chip, which is configured to store data. The storage chip 11 includes a plurality of data input/output (I/O) ports (e.g., DQ0-DQn) connected to the connection port 14. The storage chip 11 receives data input from the motherboard 20 and/or outputs stored data to the motherboard 20 through the connection port 14.

In the embodiment, the register chip 12 may be a serial presence detect (SPD) chip, which stores parameters for initializing the memory bank 10, such as, parameters of data transmission rate, capacity, working voltage, of the memory bank 10. The parameters indicate the working state of the memory bank 10, which improves the stability of the memory bank 10. The register chip 12 includes a serial data (SDA) port configured to transmit data.

The detection unit 15 is electronically connected to the storage chip 11, the register chip 12, and the connection port 14. The detection unit 15 detects whether the storage chip 11 and the register chip 12 work normally, and outputs detection signals to the motherboard 20 through the connection port 14. The motherboard 20 performs predetermined operations according to the detection signals, to indicate whether the storage chip 11 and the register chip 12 work normally.

The detection unit 15 includes two detection ports 151 (e.g., 151a and 151b) and two signal output ports 152 (e.g., 152a and 152b). The two detection ports 151 are electronically connected to the storage chip 11 and the register chip 12, respectively. The two signal output ports 152 are electronically connected two predetermined transmission pins of the connection port 14, respectively, to transmit the detection signals output by the detection unit 15 to the motherboard 20.

In this embodiment, the detection port 152a is electronically connected to each of the data I/O ports of the storage chip 11. The detection port 151b is electronically connected to the SDA port of the register chip 12. Thus, the detection unit 15 may detect whether the storage chip 11 and the register chip 12 work normally by detecting a logic voltage of each of the data I/O ports of the storage chip 11 and a logic voltage of the SDA port of the register chip 12. For example, when the detected logic voltage of each of the data I/O ports continuously changes between a logic high level voltage (e.g., 2.5V or 3.3V) and a logic low level voltage (e.g., 0V), the detection unit 15 determines that the storage chip 11 works normally and outputs a first detection signal to the motherboard 20. Otherwise, when the detected logic voltage of any of the data I/O ports does not change within a first predetermined period of time (e.g., 15 or 30 seconds), the detection unit 15 determines that the storage chip 11 is not working normally and outputs a second detection signal to the motherboard 20.

When the detected logic voltage of the SDA port of the register chip 12 continuously changes between the logic high level voltage and the logic low level voltage, the detection unit 15 determines that the register chip 12 works normally and outputs a third detection signal to the motherboard 20. Otherwise, when the detected logic voltage of the SDA port does not change within a second predetermined period of time, the detection unit 15 determines that the register chip 12 does not work normally and outputs a fourth detection signal to the motherboard 20. In one embodiment, the first and third detection signals may be high level voltage signals (e.g., 3.3V), and the second and fourth detection signals may be low level voltage signals (e.g., 0V). In other embodiments, the first and third detection signal may be low level voltage signals and the second and fourth detection signals may be high level voltage signals.

When the motherboard 20 receives the detection signals from the detection unit 15 through the connection port 14, the processor 21 of the motherboard 20 may perform the predetermined operations to indicate the working states of the storage chip 11 and the register chip 12. For example, when the first and third signals are received, the processor 21 controls a light indicator (e.g., an LED which is not shown) of the computer system 100 to emit green light to indicate that the storage chip 11 and the register chip 12 are working normally. When the second and/or fourth signals are received, the processor 21 controls the light indicator of the computer system 100 to emit red light to indicate that the storage chip 11 and/or the register chip 12 is not working normally.

Since the detection unit 15 is provided in the memory bank 10, the working states of both the storage chip 11 and the register chip 12 can be detected by the memory bank 10 and output to the motherboard 20 of the computer system 100. When a malfunction of the memory bank 10 happens, the computer system 100 can accurately detect which component of the memory bank 100 causes the malfunction. Thus, it is easy to eliminate the malfunctioning component of the memory bank 20.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A computer system, comprising:
a motherboard and a memory bank, wherein the memory bank is electronically connected to the motherboard, the memory bank comprising:
a storage chip comprising a plurality of data input/output (I/O) ports;
a register chip comprising a serial data (SDA) port;
a connection port; and
a detection unit electronically connected to the storage chip, the register chip, and the connection port;
wherein the detection unit detects a logic voltage of each of the data I/O ports and a logic voltage of the SDA port to detect whether or not each of the storage chip and the register chip works normally and outputs detection signals to the motherboard through the connection port according to the detection of the storage chip and the register chip;
the motherboard performs predetermined operations according to the detection signals, to indicate whether or not the storage chip and the register chip work normally.

2. The computer system according to claim 1, wherein the detection unit comprises two detection ports, one of the two detection ports is electronically connected to each of the data I/O ports, and another of the two detection ports is electronically connected to the SDA port.

3. The computer system according to claim 1, wherein when the detected logic voltage of each of the data I/O ports continuously changes between a logic high level voltage and a logic low level voltage, the detection unit determines that the storage chip works normally and outputs a first detection signal; and when the detected logic voltage of any of the data I/O ports does not change within a first predetermined period of time, the detection module determines that the storage chip does not work normally and outputs a second detection signal.

4. The computer system according to claim 1, wherein when the detected logic voltage of the SDA port of the register chip continuously changes between a logic high level voltage and a logic low level voltage, the detection unit determines that the register chip works normally and outputs a third detection signal to the motherboard; and when the detected logic voltage of the SDA port does not change within a second predetermined period of time, the detection unit determines that the register chip does not work normally and outputs a fourth detection signal to the motherboard.

5. The computer system according to claim 2, wherein the detection unit further comprises two signal output ports electronically connected to two predetermined transmission pins of the connection port, respectively, to transmit the detection signals output by the detection unit to the motherboard.

6. The computer system according to claim 1, wherein the motherboard further comprises a memory bank socket, and the connection port is an edge connector of the memory bank which is inserted into the memory bank socket, to establish data communication between the memory bank and the motherboard.

7. The computer system according to claim 1, wherein the storage chip is a static random access memory (SRAM) chip, a dynamic random access memory (DRAM) chip, a synchronous dynamic random access memory (SDRAM) chip, or a double data rate SDRAM (DDR SDRAM) chip.

8. The computer system according to claim 1, wherein the register chip is a serial presence detect (SPD) chip that stores parameters for initializing the memory bank.

9. A memory bank of a computer system, comprising:
a storage chip comprising a plurality of data input/output (I/O) ports;
a register chip comprising a serial data (SDA) port;
a connection port; and
a detection unit electronically connected to the storage chip, the register chip, and the connection port;
wherein the detection unit detects a logic voltage of each of the data I/O ports and a logic voltage of the SDA port to detect whether or not each of the storage chip and the register chip works normally and outputs detection signals to the motherboard through the connection port according to the detection of the storage chip and the register chip, and the motherboard performs predetermined operations according to the detection signals, to indicate whether or not the storage chip and the register chip work normally.

10. The memory bank according to claim 9, wherein the detection unit comprises two detection ports, one of the two detection ports is electronically connected to each of the data I/O ports, and another of the two detection ports is electronically connected to the SDA port.

11. The memory bank according to claim 9, wherein when the detected logic voltage of each of the data I/O ports continuously changes between a logic high level voltage and a logic low level voltage, the detection unit determines that the storage chip works normally and outputs a first detection signal; and when the detected logic voltage of any of the data I/O ports does not change within a first predetermined period of time, the detection module determines that the storage chip does not work normally and outputs a second detection signal.

12. The memory bank according to claim 9, wherein when the detected logic voltage of the SDA port of the register chip continuously changes between a logic high level voltage and a logic low level voltage, the detection unit determines that the register chip works normally and outputs a third detection signal to the motherboard; and when the detected logic voltage of the SDA port does not change within a second predetermined period of time, the detection unit determines that the register chip does not work normally and outputs a fourth detection signal to the motherboard.

13. The memory bank according to claim 10, wherein the detection unit further comprises two signal output ports which are electronically connected two predetermined transmission pins of the connection port, respectively, to transmit the detection signals output by the detection unit to the motherboard.

14. The memory bank according to claim 9, wherein the connection port is an edge connector of the memory bank which is inserted into a memory bank socket of a motherboard of the computer system, to establish data communication between the memory bank and the motherboard.

15. The memory bank according to claim 9, wherein the storage chip is a static random access memory (SRAM) chip, a dynamic random access memory (DRAM) chip, a synchronous dynamic random access memory (SDRAM) chip, or a double data rate SDRAM (DDR SDRAM) chip.

16. The memory bank according to claim 9, wherein the register chip is a serial presence detect (SPD) chip that stores parameters for initializing the memory bank.
